(19) United States
(12) Patent Application Publication
(10) Pub. No.: US 2020/0066856 A1
(43) Pub. Date: Feb. 27, 2020

(54) SEMICONDUCTOR DEVICE AND METHOD OF MANUFACTURING THE SAME

(71) Applicant: SAMSUNG ELECTRONICS CO., LTD., Suwon-si (JP)

(72) Inventors: Hyun Seung SONG, Hwaseong-si (KR); Doo Hyun LEE, Hwaseong-si (KR); Yun Il LEE, Anyang-si (KR); Jae Ran JANG, Suwon-si (KR)

(21) Appl. No.: 16/386,475

(22) Filed: Apr. 17, 2019

(30) Foreign Application Priority Data
Aug. 22, 2018 (KR) 10-2018-0097932

(51) Int. Cl. H01L 29/417; H01L 29/06; H01L 29/78; H01L 21/285

(52) U.S. Cl. CPC H01L 29/41791; H01L 21/28518; H01L 29/785; H01L 29/0653

(57) ABSTRACT

A semiconductor device and a method of manufacturing a semiconductor device, the semiconductor device including a substrate including an active fin extending in a first direction; a gate structure extending in a second direction to intersect the active fin; a source/drain region on the active fin; a metal silicide layer on the source/drain region; a filling insulating portion on the metal silicide layer, the filling insulating portion having a contact hole connected to a portion of the metal silicide layer; a protective barrier layer between the metal silicide layer and the filing insulating portion; and a contact plug in the contact hole and electrically connected to the portion of the metal silicide layer.

### CROSS-REFERENCE TO RELATED APPLICATION

Korean Patent Application No. 10-2018-0097932 filed on Aug. 22, 2018 in the Korean Intellectual Property Office, and entitled: “Semiconductor Device and Method of Manufacturing the Same,” is incorporated by reference herein in its entirety.

### BACKGROUND

### 1. Field

Embodiments relate to a semiconductor device and a method of manufacturing the same.

### 2. Description of the Related Art

Due to an increase in demand for high-performance, high-speed semiconductor devices and/or multifunctional semiconductor devices, a degree of integration in semiconductor devices has increased.

### SUMMARY

The embodiments may be realized by providing a semiconductor device including a substrate including an active fin extending in a first direction; a gate structure extending in a second direction to intersect the active fin; a source/drain region on the active fin; a metal silicide layer on the source/drain region; a filling insulating portion on the metal silicide layer, the filling insulating portion having a contact hole connected to a portion of the metal silicide layer; a protective barrier layer between the metal silicide layer and the filing insulating portion; and a contact plug in the contact hole and electrically connected to the portion of the metal silicide layer.

The embodiments may be realized by providing a semiconductor device including a substrate including a plurality of active fins extending in a first direction; a gate structure extending in a second direction, different from the first direction, to intersect the plurality of active fins; source/drain regions on the plurality of active fins on at least one side of the gate structure; an interlayer dielectric on the gate structure and the plurality of active fins, the interlayer dielectric having an opening exposing the source/drain regions; a metal silicide layer on the source/drain regions; a filling insulating portion in the opening of the interlayer dielectric, the filling insulating portion having a contact hole connected to a portion of the metal silicide layer; a first barrier layer between the metal silicide layer and the filling insulating portion; a barrier capping layer between the first barrier layer and the filling insulating portion, the barrier capping layer including a material that is different from a material of the first barrier layer; a contact plug in the contact hole and electrically connected to the source/drain regions through the metal silicide layer; and a second barrier layer between the metal silicide layer and the contact plug and between an inner sidewall of the contact hole and the contact plug.

The embodiments may be realized by providing a semiconductor device including a substrate including a plurality of active fins; source/drain regions on the plurality of active fins; a metal silicide layer on the source/drain regions; a filling-insulating portion on the metal silicide layer, the filling insulating portion having a contact hole connected to a portion of the metal silicide layer; a first barrier layer between the metal silicide layer and the filling insulating portion; a barrier capping layer between the first barrier layer and the filling insulating portion, the barrier capping layer including a material that is different from a material of the first barrier layer; a contact plug in the contact hole and electrically connected to the portion of the metal silicide layer; and a second barrier layer between the metal silicide layer and the contact plug and between an inner sidewall of the contact hole and the contact plug.

The embodiments may be realized by providing a method of manufacturing a semiconductor device, the method including forming an opening in an interlayer dielectric to expose a source/drain region; sequentially forming a metal layer and a first barrier layer on the interlayer dielectric and the source/drain region; forming a barrier capping layer on a portion of the first barrier layer corresponding to the source/drain region such that the barrier capping layer includes a material different from a material of the first barrier layer; selectively removing portions of the first barrier layer and the metal layer on at least a sidewall of the opening, using the barrier capping layer; siliciding a metal layer in contact with the source/drain region; forming a filling insulating portion to fill the opening; forming a contact hole in the filling insulating portion to expose a portion of the metal silicide layer or a portion of the first barrier layer corresponding to the portion of the metal silicide layer; and sequentially forming a second barrier layer and a contact plug in the contact hole.

### BRIEF DESCRIPTION OF THE DRAWINGS

Features will be apparent to those of skill in the art by describing in detail exemplary embodiments with reference to the attached drawings in which:

FIG. 1 illustrates a layout view of a semiconductor device according to an example embodiment;

FIGS. 2A to 2B illustrate cross-sectional views taken along lines I1-I1′ and I2-I2′ in FIG. 1, respectively;

FIG. 3 illustrates a cross-sectional view taken along line II-II′ in FIG. 1;

FIGS. 4 to 6 illustrate cross-sectional view of semiconductor devices according to example embodiments, respectively;

FIGS. 7 to 16 illustrate cross-sectional views of stages in a method of manufacturing a semiconductor device according to an example embodiment;

FIGS. 17 to 23 illustrate cross-sectional views of stages in a method of manufacturing a semiconductor device according to an example embodiment;

FIGS. 24 to 29 illustrate cross-sectional views of stages in a method of manufacturing a semiconductor device according to an example embodiment;

FIGS. 30 to 35 illustrate cross-sectional views of stages in a method of manufacturing a semiconductor device according to an example embodiment;

FIG. 36 illustrates a circuit diagram of an SRAM cell including a semiconductor device according to an example embodiment;

FIG. 37 illustrates a block diagram of an electronic apparatus including a semiconductor device according to an example embodiment; and

FIG. 38 illustrates a schematic diagram of a system including a semiconductor device according to an example embodiment.

### DETAILED DESCRIPTION

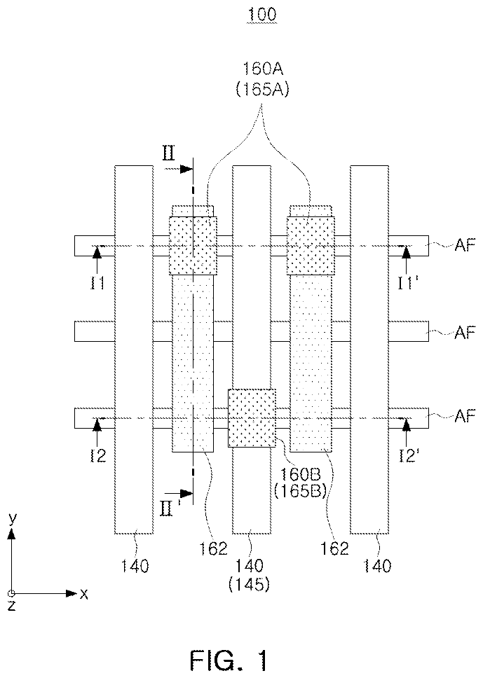

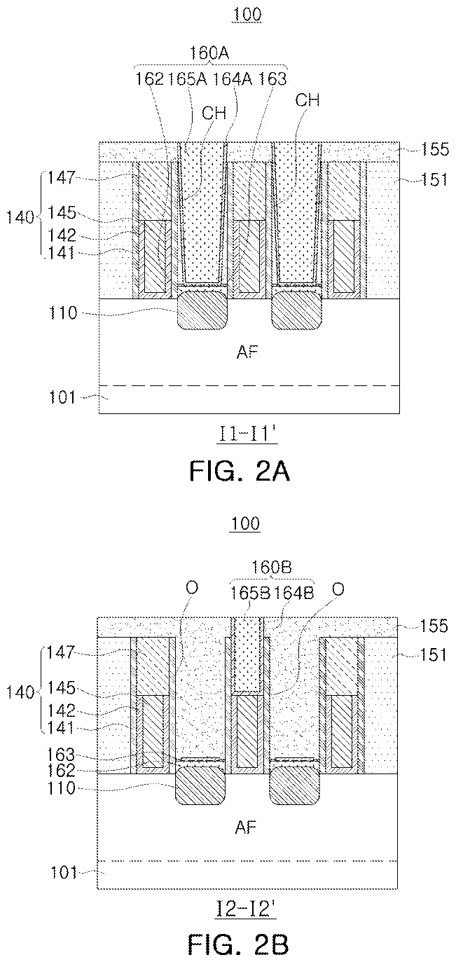

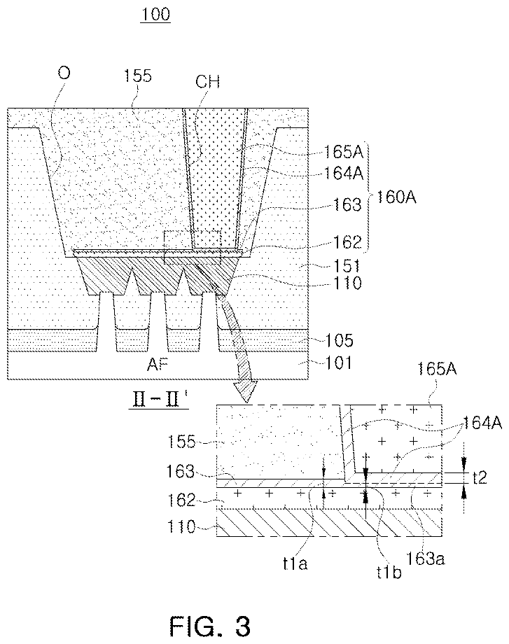

FIG. 1 illustrates a layout view of a semiconductor device according to an example embodiment. FIGS. 2A to 2B illustrate cross-sectional views taken along lines I1-I1′ and I2-I2′ in FIG. 1, respectively, and FIG. 3 illustrates a cross-sectional view taken along line II-II′ in FIG. 1.

Referring to FIGS. 1 to 3, a semiconductor device 100 may include a substrate 101 including a plurality of, e.g., three, active fins AF extending in a first direction (x direction), gate structures 140 extending in a second direction to intersect the active fins AF, and source/drain regions on both sides of the gate structures 140.

The substrate 101 may have a top surface extending in the X direction and a Y direction. The substrate 101 may include a semiconductor such as silicon (Si) or germanium (Ge), or a compound semiconductor such as silicon-germanium (SiGe), silicon carbide (SiC), gallium arsenide (GaAs), indium arsenide (InAs), or indium phosphide (InP). In an implementation, the substrate 101 may have a silicon-on-insulator (SOI) structure. The substrate 101 may include a conductive region such as an impurity-doped well or an impurity-doped structure.

Sidewalls of lower portions of the active fins AF may be covered with a device isolation layer 105 on the substrate 101. For example, the device isolation layer 105 may be formed by a shallow trench isolation (STI) process. In an implementation, the device isolation layer 105 may include a region extending to a lower portion of the substrate 101 between the active fins AF. In an implementation, the device isolation layer 105 may have a curved top surface that has a higher level as it comes closer to the active fin AF. The device isolation layer 105 may be formed of an insulating layer. For example, the device isolation layer 105 may be formed of an oxide, a nitride, or a combination thereof.

The active fins AF may be defined within the substrate 101 by the device isolation layer 105 and may extend in the first direction (e.g., x direction), as described above. The active fin AF may have a structure of an active fin protruding from the substrate 101. The active fin AF may have an upper end protruding from the top surface of the device isolation layer 105 to a predetermined height. The active fin AF may be a portion of the substrate 101 or may include an epitaxial layer grown from the substrate 101. The active fins AF on the substrate 101 may be partially recessed on both sides of the gate structures 140, and source/drain regions 110 may be on the recessed active fins AF. A portion of the active fins AF below the gate structures 140 may have a relatively high top surface. In an implementation, the active fins AF may include impurities.

The source/drain regions 110 may be on a region in which the active fins AF are recessed, on both the sides of the gate structures 140, respectively. The source/drain regions 110 may be on both sides of the gate structure 140, and/or may be disposed on at least one side on the basis of a specific gate structure 140. The source/drain regions 110 may be provided as source regions or drain regions of transistors. As illustrated in FIGS. 2A and 2B, the source/drain region 110 may have a raised source/drain (RSD) structure in which a level of a top surface ST of the source/drain region 110 is higher than a level of a top surface of the active fin AF. The source/drain regions 110 may include a semiconductor layer epitaxially grown from the active fin AF. In an implementation, relative heights of the source/drain regions 110 and the gate structures 140 may vary, depending on example embodiments. For example, top surfaces of the source/drain regions 110 may be at the same or similar height level as bottom surfaces of the gate structures 140.

A selectively grown epitaxial layer provided to the source/drain regions 110 may include silicon (Si) or silicon-germanium (SiGe). The source/drain region 110 may have a structure in which three active fins AF are merged with each other during a selective growth process.

As illustrated in FIG. 3, the source/drain regions 110 may have a substantially polygonal or pentagonal shape and the merged source/drain regions 110 may have a substantially planar top surface during formation of an opening. In an implementation, the source/drain regions 110 may have various shapes. In an implementation, the source/drain regions 120 may have one of a polygonal shape, a circular shape, and a rectangular shape.

Referring to FIG. 1, three gate structures 140 may extend in a second direction (e.g., y direction) while intersecting top surfaces of three active fins AF and are disposed in the first direction (e.g., x direction). For example, the gate structures 140 may extend in the second direction while covering top surfaces and both sidewalls of the active fins AF and a top surface of the device isolation layer 105. A plurality of MOS transistors may be at an intersection of the active fin AF and the gate structure 140. Each of the plurality of MOS transistors may include a three-dimensional MOS transistor in which a channel is formed in a top surface and both sidewalls of an active fin AF.

Referring to FIGS. 2A and 2B, each of the three gate structures 140 may include a gate spacer 141, a gate dielectric layer 142, a gate electrode 145, and a gate capping layer 147.

The gate spacer 141 may be on both side surfaces of the gate electrode 145 to insulate the source/drain regions 110 from the gate electrode 145. In an implementation, the gate spacer 141 may have a multilayer structure. The gate spacer 141 may be formed of an oxide, a nitride, or an oxynitride. In an implementation, the gate spacer 141 may be formed of a low-k dielectric material. For example, the gate spacer 141 may include a silicon nitride, a silicon oxynitride, or a combination thereof.

The gate dielectric layer 142 may be between the active fins AF and the gate electrodes 145 and may cover bottom surfaces and both sidewalls of the gate electrodes 145. In an implementation, the gate dielectric layer 142 may be on only a bottom surface of the gate electrode 145. For example, the gate dielectric layer 142 may be formed of a silicon oxide, a high-k dielectric material, or a combination thereof.

The high-k dielectric material may have a dielectric constant (e.g., about 10 to 25) higher than a dielectric constant of the silicon oxide. In an implementation, the high-k dielectric material may include, e.g., hafnium oxide, hafnium oxynitride, hafnium silicon oxide, lanthanum oxide, lanthanum aluminum oxide, zirconium oxide, zirconium silicon oxide, tantalum oxide), titanium oxide, barium strontium titanium oxide, barium titanium oxide, strontium titanium oxide, yttrium oxide, aluminum oxide, lead scandium tantalum oxide, lead zinc niobate, or combinations thereof. The gate dielectric layer 142 may be formed by an atomic layer deposition (ALD) process, a chemical vapor deposition (CVD) process, or a physical vapor deposition (PVD) process.

The gate electrode 145 may include a conductive material, e.g., a metal nitride such as titanium nitride (TiN), tantalum nitride (TaN) or tungsten nitride (WN) and/or a metallic material such as aluminum (Al), tungsten (W) or molybdenum (Mo), or a semiconductor material such as doped polysilicon. In other embodiments, the gate electrodes 145 may have a multilayer structure including two or more layers.

The gate capping layer 147 may be above the gate electrode 145. A bottom surface and side surfaces of the gate capping layer 147 may be surrounded by the gate electrode 145 and the gate spacer 141, respectively.

An interlayer dielectric (ILD) 151 may cover top surfaces of the device isolation layers 105, the source/drain regions 110, and the gate structures 140. The interlayer dielectric 151 may include, e.g., at least one of an oxide, a nitride, and an oxynitride and may include a low-k dielectric material. In an implementation, the interlayer dielectric 151 may include tetraethyl orthosilicate (TEOS), undoped silicate glass (USG), phosphosilicate glass (PSG), borosilicate glass (BSG), borophosphosilicate glass (BPSG), fluoride silicate glass (FSG), spin on glass (SOG), tonen silazene (TOSZ), or combinations thereof. The interlayer dielectric 151 may be formed using CVD, spin coating, or the like.

As illustrated in FIG. 1, a first contact structure 160A may be connected to the source/drain region 110 to extend in a direction (e.g., z direction) perpendicular to a top surface of the substrate 101. In an implementation, the second contact structure 160B may extend in the z direction to be connected to the gate electrode 145 of the gate structure 140.

Referring to FIGS. 2A and 3, the first contact structure 160A of the present embodiment may include a metal silicide layer 162, a protective barrier layer (hereinafter also referred to as “first barrier layer”), a conductive barrier layer 164A (hereinafter also referred to “second barrier layer”), and a first contact plug 165A.

The metal silicide layer 162 may cross the source/drain regions 110 exposed by an opening O of the interlayer dielectric 151. The metal silicide layer 162 may help improve contact resistance of the first contact structure 160A and the source/drain region 110. The metal silicide layer 162 may have a sufficient contact area with the source/drain regions 110.

In an implementation, the metal silicide layer 162 is formed by reacting with a semiconductor material (e.g., silicon (Si), silicon-germanium (SiGe), germanium (Ge), or the like). The metal silicide layer 162 may include a silicide layer containing at least one of titanium (Ti), cobalt (Co), nickel (Ni), tantalum (Ta), and platinum (Pt). In an implementation, the metal silicide layer 162 may be expressed as MSiₓD_{y}, where M denotes a metal, D denotes an element different from M and silicon (Si), 0<x≤3, and 0≤y≤1. M may be titanium (Ti), cobalt (Co), nickel (Ni), tantalum (Ta), platinum (Pt), or combinations thereof, and D may be germanium (Ge), carbon (C), argon (Ar), krypton (Kr), xenon (Xe), or combinations thereof.

A filling insulating portion 155 having a contact hole CH connected to one region of the metal silicide layer 161 may be on the opening O of the interlayer dielectric 151. The region connected to the contact hole CH may provide a region to be in contact with the first contact plug 165A.

As described above, a substantial contact with the source/drain region 110 may secure a sufficient area through the metal silicide layer 162 and may electrically connect the first contact plug 165A having a small size, defined as the contact hole CH of the filling insulating portion 155, to some regions of the metal silicide layer 162.

The first contact structure 160A of the present embodiment may help ensure a suitable short margin between contacts even under scale-down conditions without increasing contact resistance and may help reduce parasitic capacitance formed between the contacts. The filling insulating portion 155 may use an insulating material having a low dielectric constant for a sufficient capacitance reduction effect and may include, e.g., a material similar to a material of the interlayer dielectric 151.

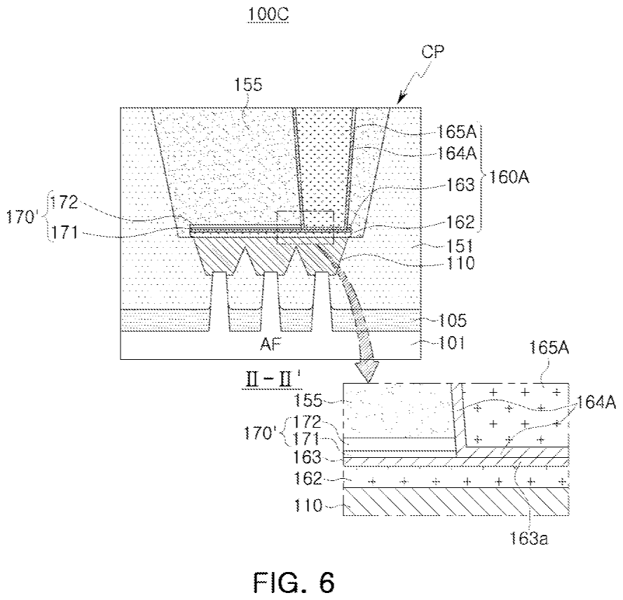

In an implementation, the filling insulating portion 155 of the present embodiment may cover the top surface of the gate structure 140, as shown in FIGS. 2A and 2B. In an implementation, the filling insulating portion 155 may form a surface substantially planar with the top surface of the gate structure 140 (see FIG. 6).

Referring to FIGS. 2A to 3, the protective barrier layer 163 may be on the metal silicide layer 162. The protective barrier layer 163 of the present embodiment may help prevent a silicide from being damaged in a subsequent process or being oxidized during a thermal treatment, after formation of the metal silicide layer 162. As a result, an undesirable resistance increase may be suppressed.

In an implementation, the protective barrier layer 163 may have substantially the same area as the metal silicide layer 162. As illustrated in FIG. 3, the protective barrier layer 163 may be between the metal silicide layer 162 and the filling insulating portion 155 and may further include a portion 163a extending to one region of the metal silicide layer 162.

In this case, the protective barrier layer 163 may include a conductive material similar to a material of the conductive barrier layer 164A. In an implementation, at least one of the protective barrier layer 163 and the conductive barrier layer 164A may include, e.g., titanium nitride (TiN), tantalum nitride (TaN), aluminum nitride (AlN), or tungsten nitride (WN). In an implementation, together with the conductive barrier layer 164A, the first contact plug 165A may be electrically connected to the metal silicide layer 162 through the protective barrier layer 163 to be used as a contact for source/drain regions.

In an implementation, the extending portion 163a of the protective barrier layer 163 may have a thickness t1b that is smaller than a thickness t1a of another portion of the protective barrier layer 163. The thickness difference will be appreciated as a result obtained when the extending portion 163a of the protective barrier layer 163 is partially etched. The conductive barrier layer 164A and the protective barrier layer 163 may be formed using processes different from each other, and their thicknesses may be different from each other.

In an implementation, the protective barrier layer 163 may be formed of the same material as the conductive barrier layer 164A. For example, a portion of the protective barrier layer 163 and the conductive barrier layer 164A below the contact plug 165A may not be distinguished from each other. In an implementation, a total thickness (e.g., t2+t1b) of the portion of the protective barrier layer 163 and the conductive barrier layer 164A below the first contact plug 165A may be greater than the thickness t1a of another part of the protective barrier layer 163.

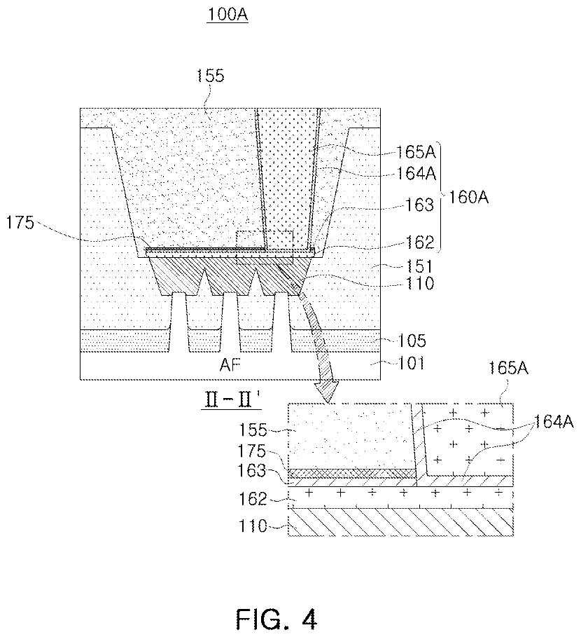

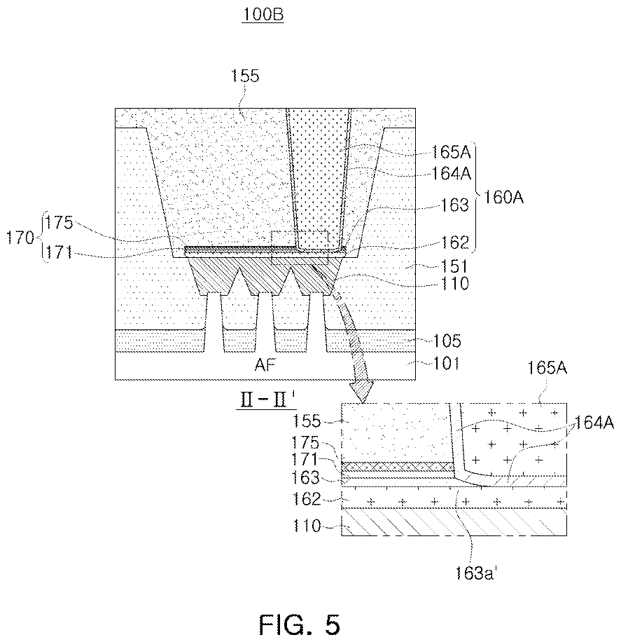

In an implementation (see FIGS. 4 and 5), the extending portion 163a may be entirely or partially removed during formation of the contact hole CH.

Referring to FIG. 2B, similarly to the first contact structure 160A, the second contact structure 160B may include a conductive barrier 164B and a second contact plug 165B and may be connected to the gate electrode 165.

The metal silicide layer 162 of the first contact structure 160A of the present embodiment may have a bar shape extending in the y direction, on the basis of an x-y plane, as illustrated in FIG. 1. In an implementation, the first contact plug 165A may have a circular, elliptical, or polygonal shape in a certain region having the bar shape. In an implementation, the second contact structure 160B may have a circular, elliptical, or polygonal cross section (on the basis of the x-y plane). In an implementation, the first and second contact plugs 165A and 165B may include tungsten (W), cobalt (Co), molybdenum (Mo), alloys thereof, or combinations thereof. According to a material for forming a contact plug, the contact plug may be directly formed in a contact hole without formation of the conductive barrier layers 164A and 164B.

As described above, the first contact structure 160A of the present embodiment may electrically connect the contact plug 165A (having a small size, defined as the contact hole CH of the filling insulating portion 155) to some regions of the metal silicide layer 162 while securing a sufficient contact area through the metal silicide layer 162 across the source/drain regions 110. As a result, a short margin between contacts may be ensured and parasitic capacitance may be reduced without increasing contact resistance.

In an implementation, the protective barrier layer 163 may be on the metal silicide layer 162 to help prevent a silicide from being damaged in a subsequent process or being oxidized during a thermal treatment, after formation of the metal silicide layer 162. As a result, sufficiently low resistance may be stably maintained.

In an implementation, a barrier capping layer may be additionally provided on a protective barrier layer. The barrier capping layer may be provided with various structures.

FIGS. 4 to 6 illustrate semiconductor devices including a barrier capping layer according to various embodiments and will be appreciated as cross-sectional views taken along line II-II′ similarly to the cross-section in FIG. 3.

Referring to FIG. 4, a semiconductor device 100A will be appreciated to have a structure similar to the structure illustrated in FIG. 3, except that a barrier capping layer 175 may be additionally provided on a protective barrier layer 163 and a position of a bottom surface of a contact hole CH may be different. Therefore, the description of the example embodiment illustrated in FIGS. 1 to 3 will be incorporated in the description of the present embodiment unless specially stated to the contrary.

As illustrated in FIG. 4, a barrier capping layer 175 may be on a protective barrier layer 163. The barrier capping layer 175 may be a mask to selectively remove the protective barrier layer 163 and a metal silicide layer 162 (or a metal layer during a process) during a process of forming a first contact structure 160A. The barrier capping layer 175 may include a material that is different from a material of the protective barrier layer 163.

The barrier capping layer 175 of the present embodiment may have a single-layer structure including a silicon oxide or a silicon nitride. In an implementation, the protective barrier layer 163 may be a titanium nitride (TiN) layer and the barrier capping layer 175 may be a silicon nitride layer.

The barrier capping layer 175 may include an insulating material, and the barrier capping layer 175 may be removed from a bottom surface of a contact hole CH during formation of the contact hole CH. In the case in which materials for forming the barrier capping layer 175 and the protective barrier layer 163 have low selectivity under an etching condition for forming the contact hole CH, the protective barrier layer 163 on the bottom surface of the contact hole CH may also be removed, similarly to the present embodiment. Similarly to the previous embodiment (see FIG. 3), in the case in which the protective barrier layer 163 is formed of a conductive material, after only the barrier capping layer 175 is removed while the protective barrier layer 163 remains, a conductive barrier layer 164A and a contact plug 165A may be removed.

Referring to FIG. 5, a semiconductor device 100B may be appreciated to have a structure similar to the structure illustrated in FIG. 3, except that a barrier capping layer 170 having a double-layer structure is additionally provided on a protective barrier layer 163 and a position of a bottom surface of a contact hole CH is different. Therefore, the description of the example embodiment illustrated in FIGS. 1 to 3 will be incorporated in the description of the present embodiment unless specially stated to the contrary.

A barrier capping layer 170 employed in the present example may have a double-layer structure including different materials. For example, the barrier capping layer 170 may include a first layer 171 including a silicon oxide and a second layer 175 including a silicon nitride.

The barrier capping layer 170 may be removed from the bottom surface of the contact hole CH during formation of the contact hole CH. In this case, a portion of the protective barrier layer 163 on the bottom surface of the contact hole CH may also be removed in such a manner that only a region 163a′ may remain.

Referring to FIG. 6, a semiconductor device 100C may be appreciated to have a structure similar to the structure illustrated in FIG. 3, except that another type of barrier capping layer 170 is additionally provided on a protective barrier layer 163, a position of a bottom surface of a contact hole CH is different, and a filling insulating portion 155 is removed from a top surface of an interlayer dielectric 151. Therefore, the description of the example embodiment illustrated in FIGS. 1 to 3 will be incorporated into the description of the present embodiment unless specially stated to the contrary.

A barrier capping layer 170′ of the present embodiment may have a double-layer structure. Unlike the previous embodiment, the barrier capping layer 170′ may have a double-layer structure in which two different layers are formed of the same material. For example, the barrier capping layer 170′ may include a first layer 171 and a second layer 172 that are both formed of silicon oxide. For example, the first layer 171 may be densely formed using atomic layer deposition (ALD) and the second layer 172 may be formed using chemical vapor deposition (CVD), and the second layer 172 may be deposited on the first layer 171 using CVD. For example, although the first layer 171 and the second layer 172 may be formed of the same material, the first layer 171 and the second layer 172 may exhibit different physical properties, e.g., different densities. As a result, a boundary between the first and second layers 171 and 172 may be distinguished. In an implementation, the first and second layers 171 and 172 may not be distinguished as different layers, even when they are formed by different deposition processes, or the second layer 172 may not be distinguished from the filling insulating portion 155 when the second layer 172 is formed of the same material as the filling insulating portion 155. In an implementation, the barrier capping layer 170 may not be confirmed or may appear as only a single layer.

The barrier capping layer 170′ may be removed from the bottom surface of the contact hole CH during formation of the contact hole CH. As in the present embodiment, in the case in which the barrier capping layer 170′ is formed of an oxide, the barrier capping layer 170′ may be removed while the contact hole CH is formed in the filling insulating portion 155 formed of the same or similar silicon oxide.

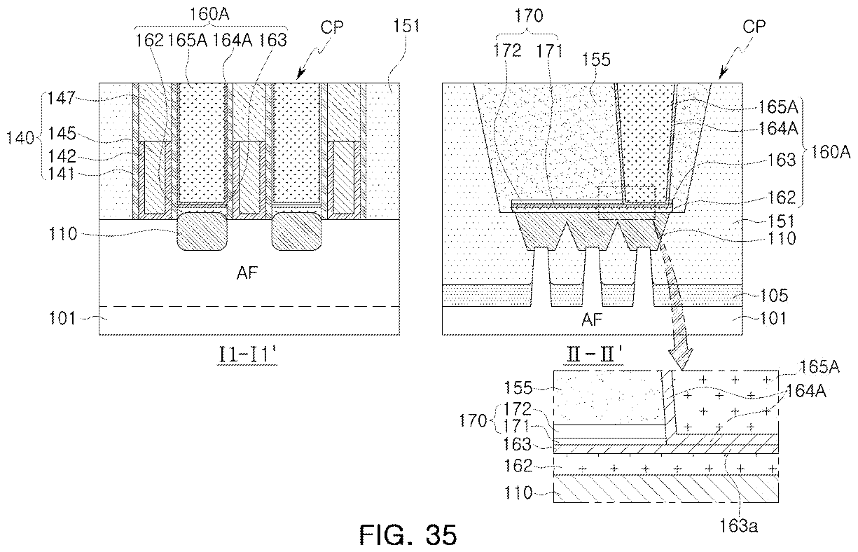

In an implementation, a polishing process such as chemical mechanical polishing (CMP) process may be performed to remove the filling insulating portion 155 on a top surface of the interlayer dielectric 151. The interlayer dielectric 151 and the filling insulating portion 155 may have a substantially planar top surface CP. In this case, a gate capping layer having a gate structure may be exposed (see FIG. 35). A contact hole may be formed using a self-alignment process.

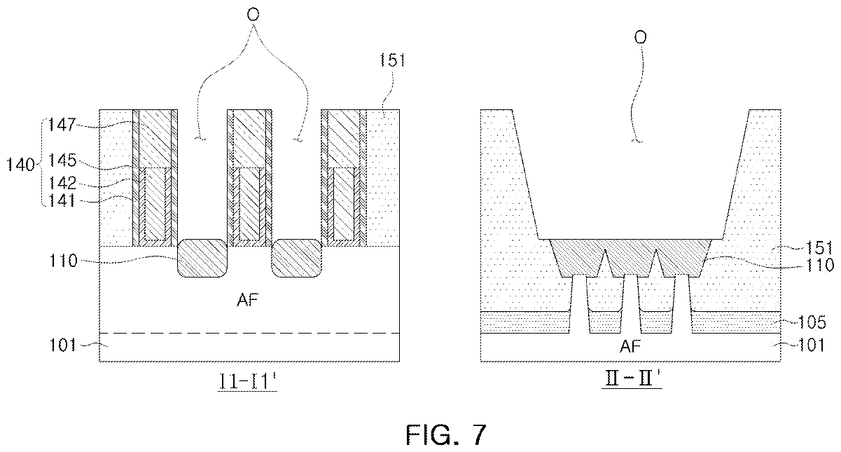

FIGS. 7 to 16 illustrate cross-sectional views of stages in a method of manufacturing a semiconductor device according to an example embodiment. The method of manufacturing a semiconductor device according to the present embodiment will be appreciated as a method of manufacturing the semiconductor device 100 illustrated in FIGS. 1 to 3.

Referring to FIG. 7, an opening O may be formed in an interlayer dielectric 151 to expose a source/drain region 110.

The opening O may be formed using a photolithography process. The source/drain region 110 formed across three active fins AF may be opened or exposed by the opening O. The interlayer dielectric 151 may be recessed along the opening O on the top surface of the source/drain region 110. As shown in the drawing, a recessed bottom surface may be a relatively planar surface. In an implementation, a top surface may be formed to be less planar or curved according to etching conditions or the like.

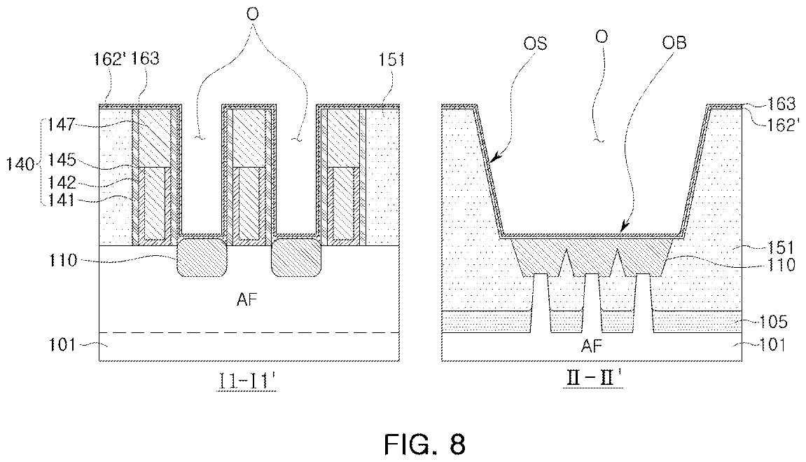

Referring to FIG. 8, a metal layer 162′ and a first barrier layer 163 may be sequentially formed on the interlayer dielectric 151 and the source/drain region 110.

The metal layer 162′ may include a metallic material for a metal silicide. For example, the metallic material may include titanium (Ti), cobalt (Co), nickel (Ni), tantalum (Ta), platinum (Pt), or combinations thereof. The metal layer 162′ and the first barrier layer 163 may be sequentially formed relatively conformally on a sidewall OS and a bottom surface OB of the opening O and on the top surface of the interlayer dielectric 151. For example, the first barrier layer 163 may include titanium nitride (TiN), tantalum nitride (TaN), aluminum nitride (AlN), tungsten nitride (WN), or combinations thereof. In an implementation, the metal layer 162′ may be a titanium (Ti) layer and the first barrier layer 163 may be a titanium nitride (TiN) layer. This process may be performed using physical vapor deposition (PVD), CVD, or ALD.

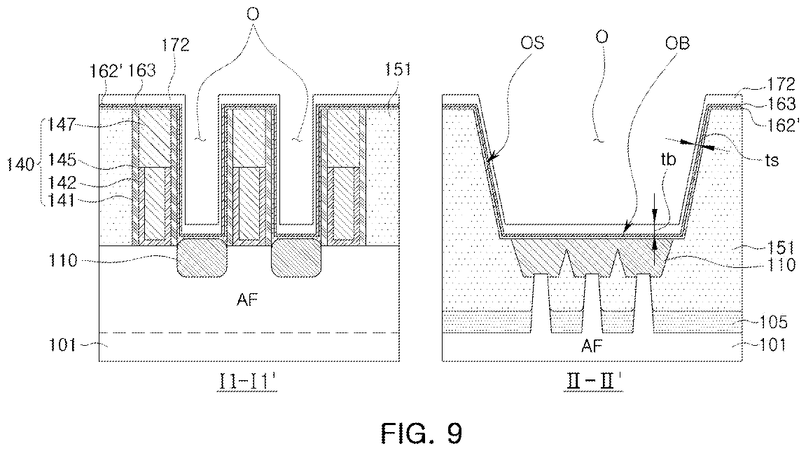

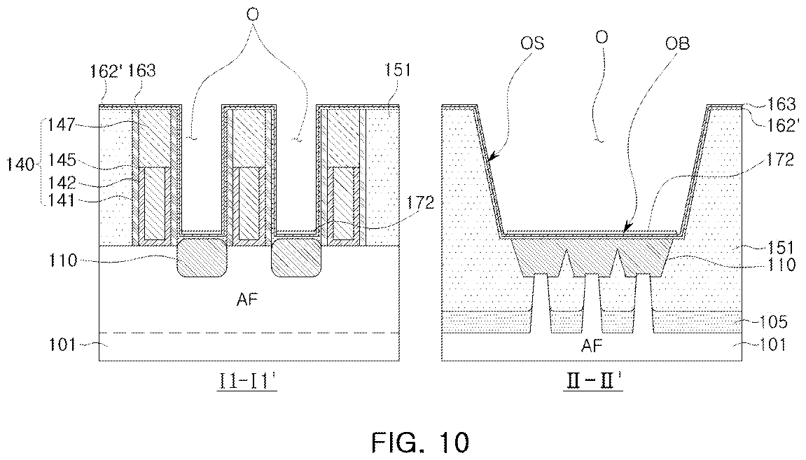

Referring to FIG. 9, a barrier capping layer 172 may be formed on the interlayer dielectric 151 and the source/drain region 110.

The barrier capping layer 172 formed on the side wall OS of the opening O may have a thickness ts that is less than a thickness of other portions of the barrier capping layer 172. The barrier capping layer 172 may be deposited on an inclined sidewall OS of the opening O to have a relatively small thickness ts and may be formed on the top surface of the interlayer dielectric 151, being a planar surface, and the bottom surface OB of the opening O to have a relatively greater thickness tb. This process may be performed using high-density plasma (HDP) CVD.

The barrier capping layer 172 of the present embodiment may include a silicon oxide or a silicon nitride. For example, the barrier capping layer 172 may include a silicon oxide layer. In an implementation, a silicon oxide layer may be formed using ALD to a thickness of several tens of angstroms before a silicon oxide layer is formed using HDP CVD.

Referring to FIG. 10, wet etching may be performed until a portion of the barrier capping layer 172 on the sidewall OS of the opening O is removed.

Even after the portion of the barrier capping layer 172 on the sidewall OS of the opening O is removed, the barrier capping layer 172 on the bottom surface OB of the opening O (having been formed with a relatively great thickness tb) may remain. The remaining barrier capping layer 172 may be present only in a portion of the first barrier layer 163 corresponding to the source/drain region 110. In a subsequent process, the barrier capping layer 172 may be used as a mask to selectively remove the metal layer 162′ and the first barrier layer 163.

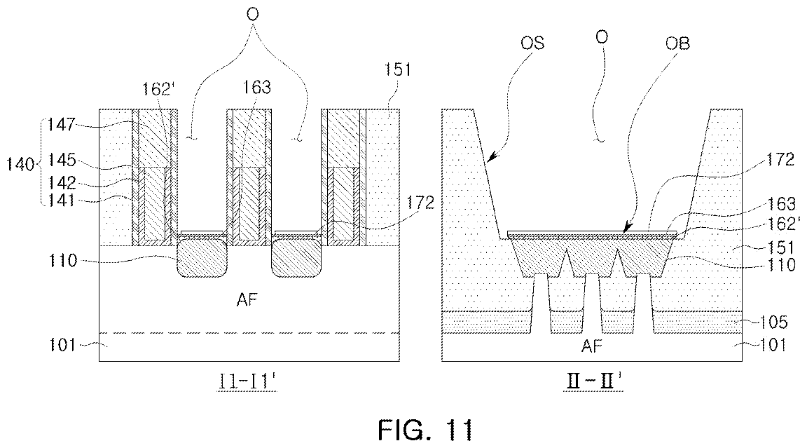

Referring to FIG. 11, the metal layer 162′ and the first barrier layer 163 may be selectively removed using the barrier capping layer 172 as a mask.

In the selective removal process, portions of the metal layer 162′ and the first barrier layer 163 on the sidewall OS of the opening O and the top surface of the interlayer dielectric 151 may be selectively removed. This process may be performed by wet etching.

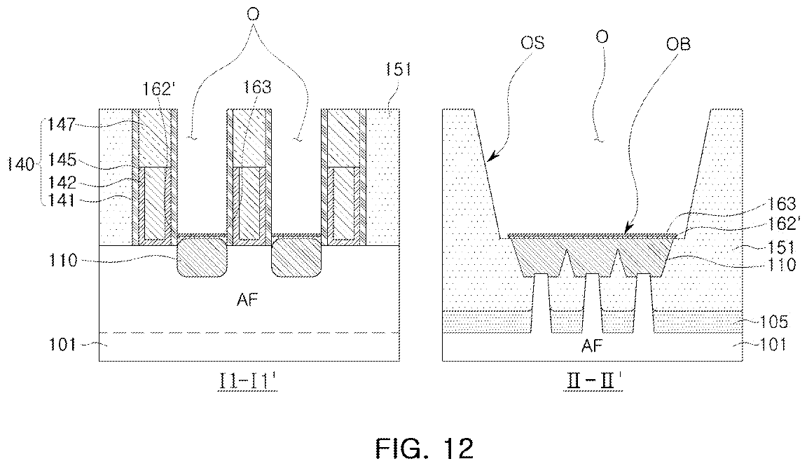

Referring to FIG. 12, after the selective removal process, the barrier capping layer 172 (previously used as a mask) may be removed from the first barrier layer 163.

As described above, the barrier capping layer 172 (formed of e.g., SiO₂) may be formed of a material having a selectivity (e.g., etch selectivity) with respect to the first barrier layer 163 (formed of, e.g., TiN), and the barrier capping layer 172 may be easily removed by a selective wet etching process. As such, when the barrier capping layer 172 is removed, the first barrier layer 163 may be directly connected to or directly contact the filling insulating portion 155 in an ultimate structure (see FIG. 3).

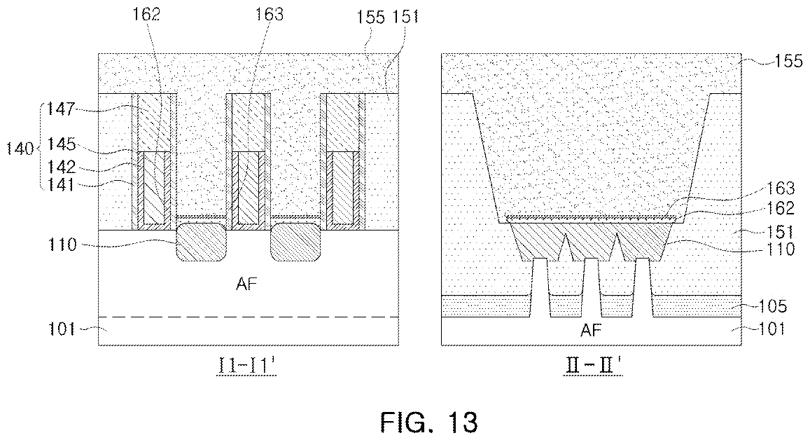

Referring to FIG. 13, a metal layer in contact with the source/drain region 110 may be silicided and a filling insulating portion is formed to fill the opening O.

The silicidation process may include performing an annealing process for reacting with silicon (e.g., the source/drain region 110). The silicidation process may be performed in the preceding step. For example, after the step of forming the metal layer 162′ and the first barrier layer 163 (FIG. 8), the silicidation process may be performed in any step. A filling insulating portion 155 may be formed to fill the opening O. As in the present embodiment, the filling insulating portion 155 may cover the top surface of the interlayer dielectric 151.

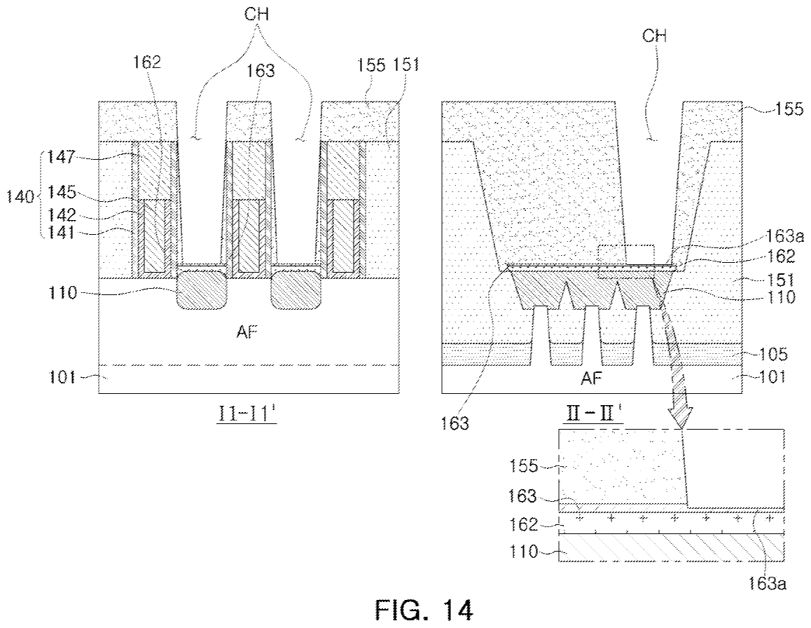

Referring to FIG. 14, a contact hole CH may be formed in the filling insulating portion 155 to expose a portion of the first barrier layer 163.

The first barrier layer 163 may be formed of a conductive material, and electrical connections between a first contact plug 165A formed in a subsequent process and the metal silicide layer 162 may be ensured even if only a portion of the first barrier layer 163 remains. In the present embodiment, an exposed region of the first barrier layer 163 may be etched during formation of the contact hole CH to have a thickness less than a thickness of other portions of the first barrier layer 163. In an implementation, a contact hole for a first contact structure connected to a gate electrode may also be formed during formation of the contact hole CH (see FIG. 2B).

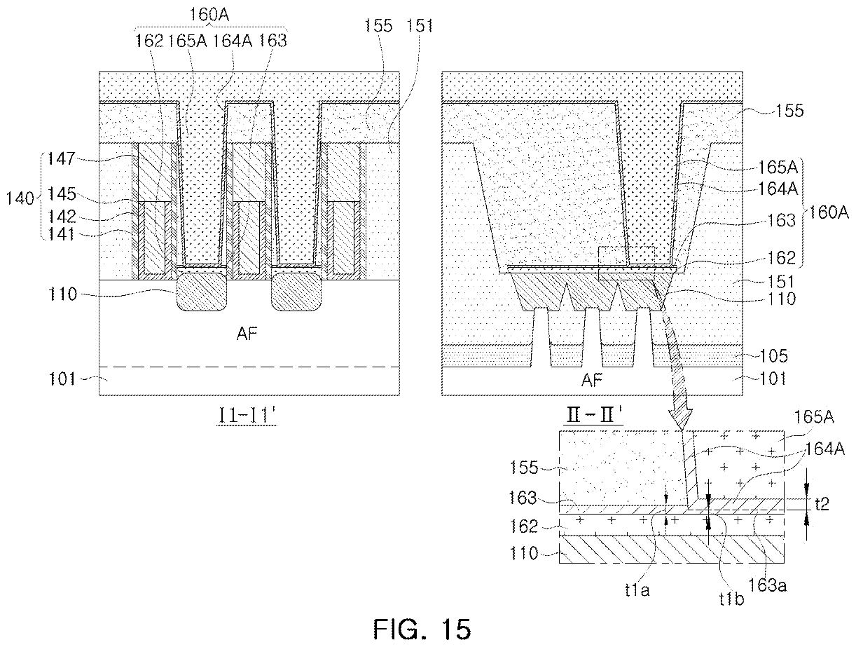

Referring to FIG. 15, a second barrier layer 164A and a first contact plug 165A may be sequentially formed in the contact hole CH.

The second barrier layer 164A may be a conductive barrier layer, serving to help prevent diffusion of a material of the first contact plug 165A. For example, the second barrier layer 164A may be formed using a process such as ALD, CVD, or the like and may include at least one of titanium nitride (TiN), tantalum nitride (TaN), aluminum nitride (AlN), and tungsten nitride (WN). The first contact plug 165A may include tungsten (W), cobalt (Co), or molybdenum (Mo). In an implementation, the first contact plug 165A may include aluminum (Al) or copper (Cu). In an implementation, the second barrier layer 164A may be omitted.

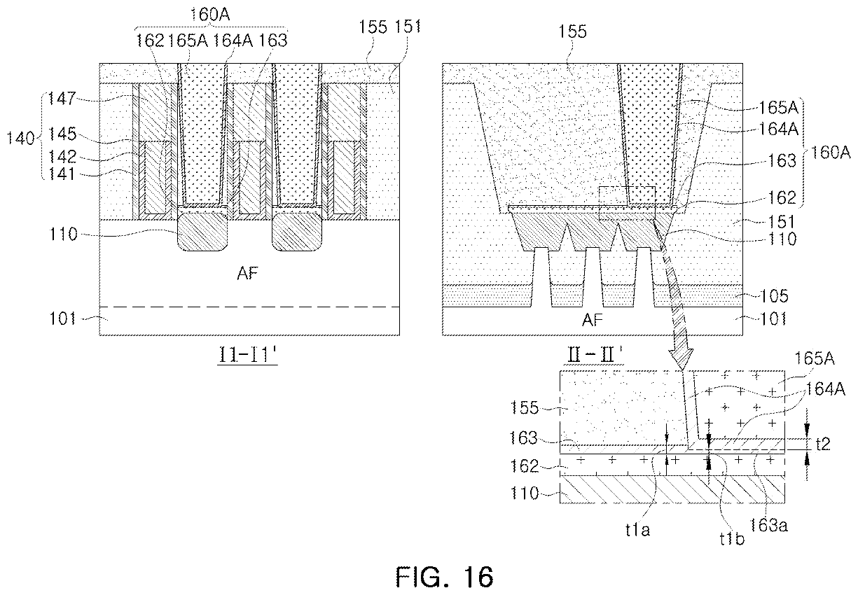

As illustrated in FIG. 16, portions of the second barrier layer 164A and the first contact plug 165A on the filling insulating portion 155 may be removed through polishing or etch back to provide a planarized surface.

As a subsequent process, a metallization process may be performed. For example, an additional interlayer dielectric may be formed, a metal via may be formed in the additional interlayer dielectric to be connected to first and second contact structures, and a metal interconnection having a desired shape may be formed. Such a metal via and such a metal interconnection may be formed using a damascene process.

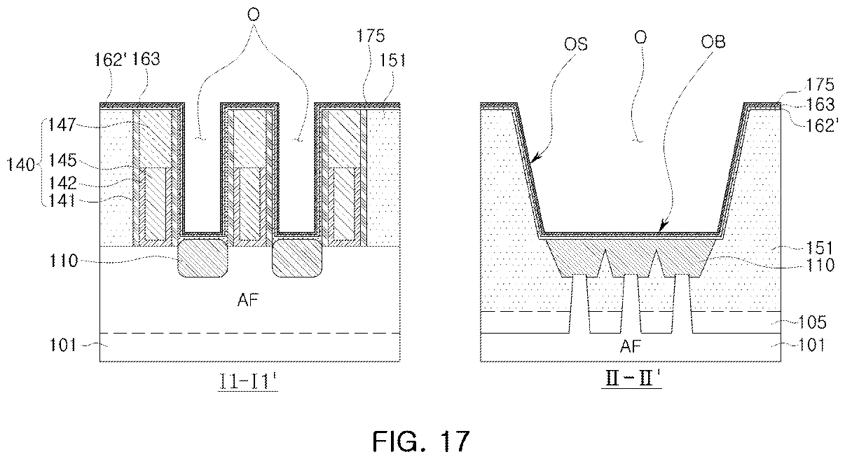

FIGS. 17 to 23 illustrate cross-sectional views of stages in a method of manufacturing a semiconductor device according to an example embodiment. The method of manufacturing a semiconductor device according to the present embodiment will be appreciated as a method of manufacturing the semiconductor device 100A illustrated in FIG. 4.

Referring to FIG. 17, after the resultant structure illustrating in FIG. 8, for example, the metal layer 162′ and the first barrier layer 163 may be sequentially formed, and a barrier capping layer 175 may be formed on the interlayer dielectric 151 and the source/drain region 110. The barrier capping layer 175 of the present embodiment may be a silicon nitride layer. The first barrier layer 163 may include titanium nitride (TiN), tantalum nitride (TaN), aluminum nitride (AlN), tungsten nitride (WN), or combinations thereof.

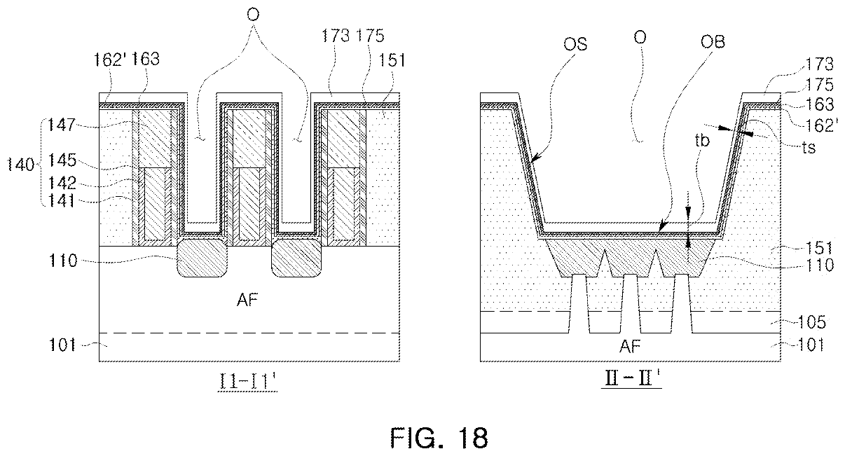

Referring to FIG. 18, a mask layer 173 may be formed on the barrier capping layer 175. The mask layer 173 of the present embodiment may be formed in such a manner that a thickness is of a portion disposed on the sidewall OS of the opening O is smaller than a thickness of other portions (e.g., the thickness tb of the bottom surface OB of the opening O). The mask layer 173 may be formed using an HDP CVD process, similarly to the barrier capping layer 172 in the previous embodiment. The mask layer 173 of the present embodiment may include a material (e.g., silicon oxide) different from a material of the barrier capping layer 175.

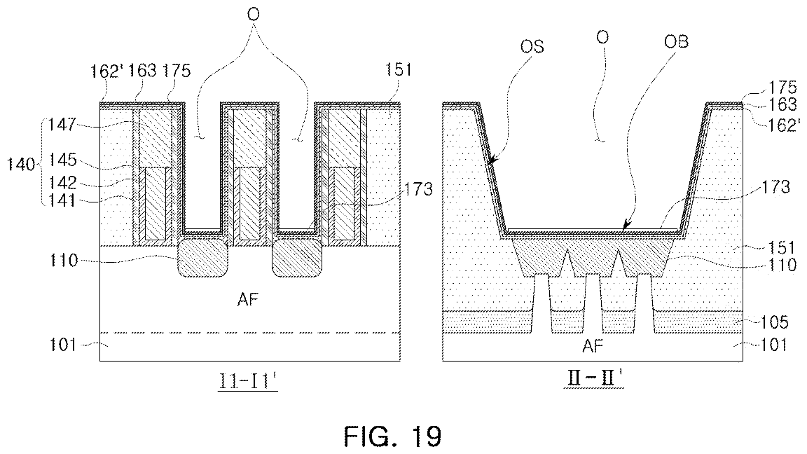

Referring to FIG. 19, wet etching is performed until a portion of the mask layer 173 on the sidewall OS of the opening O is removed. Even after the portion of the mask layer 173 on the sidewall OS of the opening O is removed, the mask layer 173 on the bottom surface OB of the opening O (previously formed to have the relatively great thickness tb) may remain. The remaining mask layer 173 may only be present in a portion of the barrier capping layer 175, corresponding to the source/drain region 110. In a subsequent process, the mask layer 173 may be used as a mask to selectively remove barrier capping layer 175.

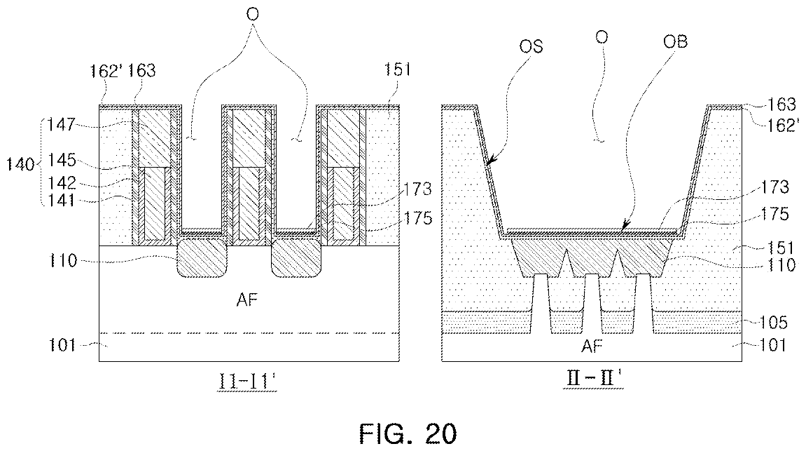

Referring to FIG. 20, by using the remaining mask layer 173, the portion of the barrier capping layer 175 on the sidewall OS of the opening O may be removed and only the portion of the barrier capping layer 175 on the bottom surface OB of the opening O, e.g., only the portion corresponding to the source/drain region 110, may remain. This process may be performed using wet etching.

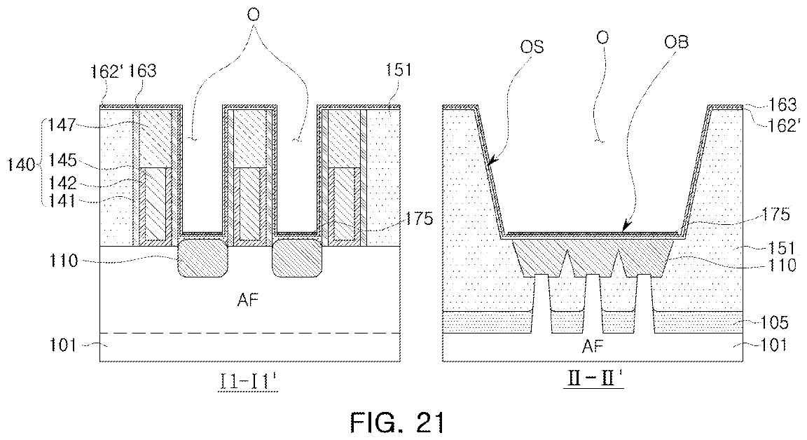

Referring to FIG. 21, the mask layer 173 may be removed from the barrier capping layer 175. The mask layer 173 may be removed using a wet etching process to expose the barrier capping layer 175.

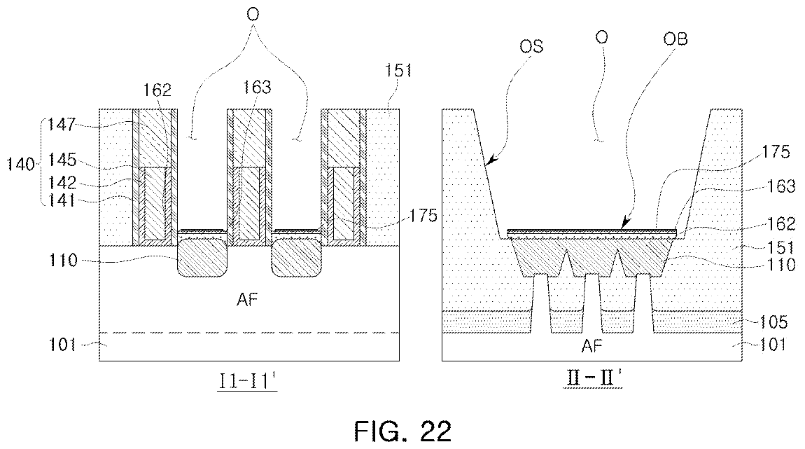

Referring to FIG. 22, the metal layer 162′ and the first barrier layer 163 may be selectively removed using the barrier capping layer 175 as a mask. In this selective removal process, portions of the first barrier layer 163 and the metal layer 162′ on the sidewall OS of the opening O and the top surface of the interlayer dielectric 151 may be selectively removed. This process may be performed using wet etching. In this step, an annealing process for the silicidation may be performed. In an implementation, and the silicidation process may be performed in a preceding step.

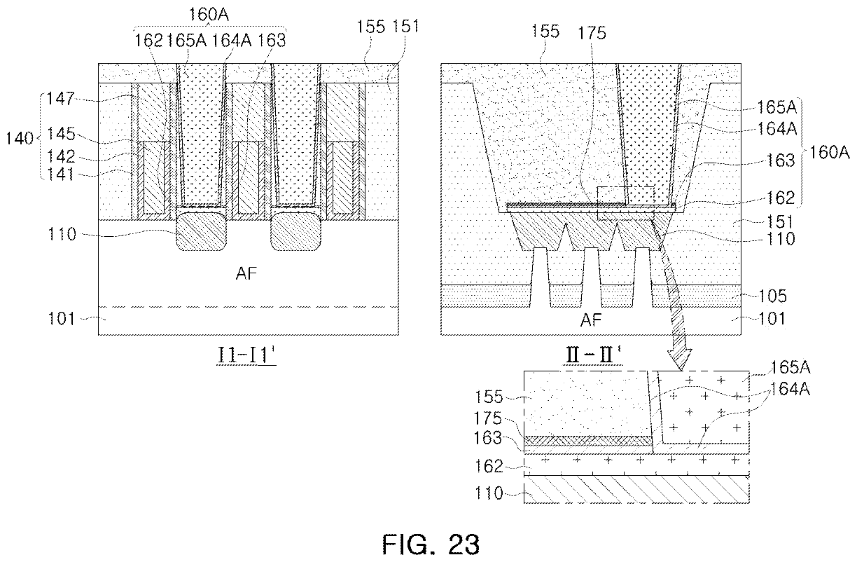

Referring to FIG. 23, a filling insulating portion 155 may fill the opening O, a contact hole CH may be formed in the filling insulating portion 155 to expose one region of the metal silicide layer 162, and a second barrier layer 164A and a first contact plug 165A may be sequentially formed in the contact hole CH. A series of processes may be performed similarly to the process described with reference to FIGS. 14 to 16. In an implementation, most of the first barrier layer 163 may be removed from a bottom surface of the contact hole CH together with the barrier capping layer 175 during formation of the contact hole CH to expose one region of the metal silicide layer 162. The semiconductor device 100A manufactured according to the present embodiment may include a barrier capping layer 175 between the first barrier layer 163 and the filing insulating layer 155, as illustrated in FIG. 4.

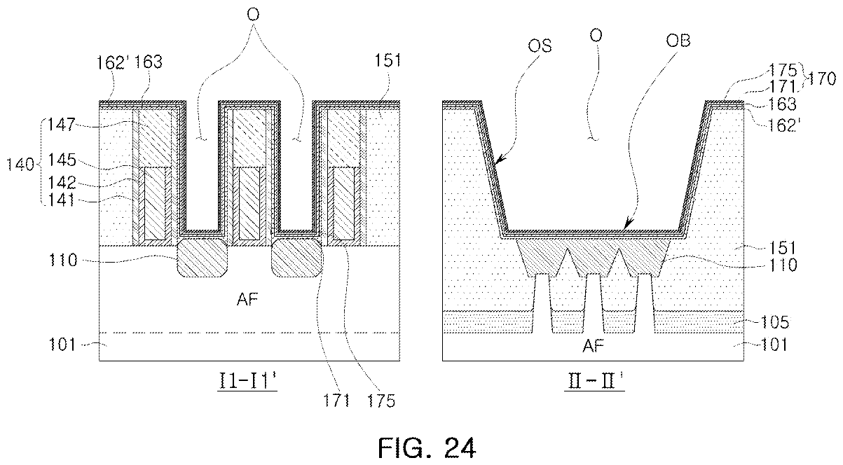

FIGS. 24 to 29 illustrate cross-sectional views of stages in a method of manufacturing a semiconductor device according to an example embodiment. The method of manufacturing a semiconductor device according to the present embodiment will be appreciated as a method of manufacturing the semiconductor device 100B illustrated in FIG. 5.

Referring to FIG. 24, after the resultant structure illustrating in FIG. 8, e.g., the metal layer 162′ and the first barrier layer 163 may be sequentially formed, and a barrier capping layer 170 may be formed on the interlayer dielectric 151 and the source/drain region 110. The barrier capping layer 170 of the present embodiment may have a double-layer structure including first and second layers 171 and 175 different from each other. For example, the first layer 171 may be a silicon oxide layer and the second layer 175 may be a silicon nitride layer. The first layer 171, e.g., a silicon oxide layer, may be deposited using atomic layer deposition (ALD).

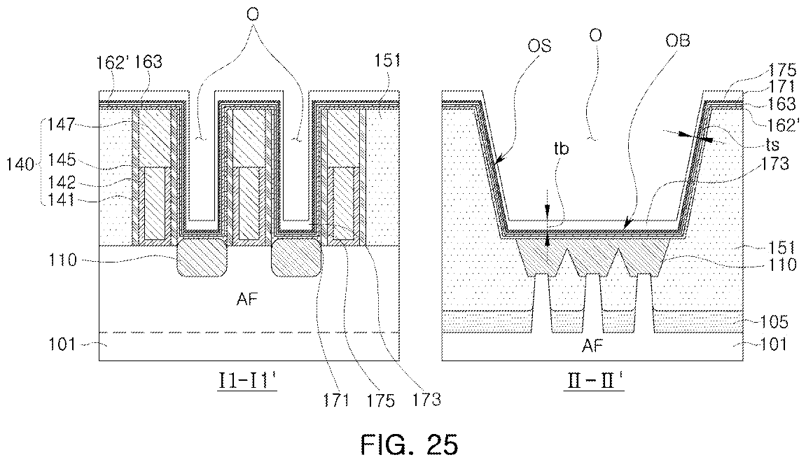

Referring to FIG. 25, a mask layer 173 may be formed on the barrier capping layer 170. The mask layer 173 of the present embodiment may be formed in such a manner that a thickness is of a portion on the sidewall OS of the opening O is smaller than a thickness of other portions (e.g., the thickness tb of the bottom surface OB of the opening O). The mask layer 173 may be formed using an HDP CVD process, similarly to the barrier capping layer 172 in the previous embodiment. The mask layer 173 of the present embodiment may include a material (e.g., silicon oxide) different from a material of the barrier capping layer 170.

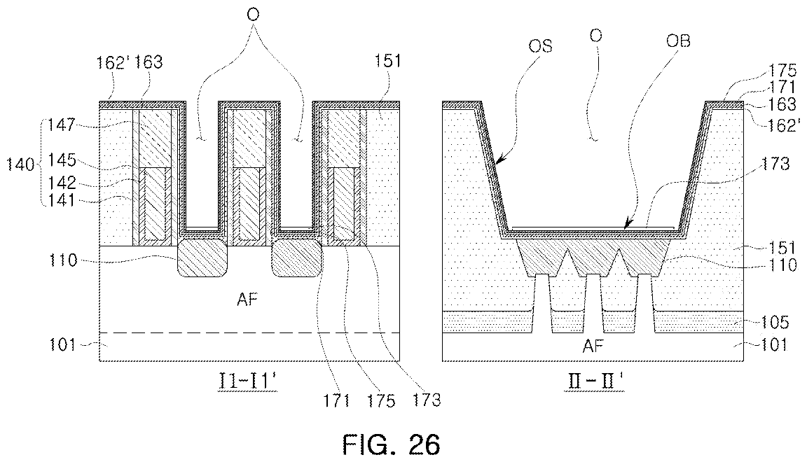

Referring to FIG. 26, wet etching may be performed until a portion of the mask layer 173 on the sidewall OS of the opening O is removed. Even after the portion of the mask layer 173 on the sidewall OS of the opening O is removed, the mask layer 173 on the bottom surface OB of the opening O (previously formed to have the relatively great thickness tb) may remain. The remaining mask layer 173 may be present only on a portion of the second layer 175 of the barrier capping layer 170 corresponding to the source/drain region 110. In a subsequent process, the mask layer 173 may be used as a mask to selectively remove the first layer 171 and second layer 175 of the barrier capping layer 170.

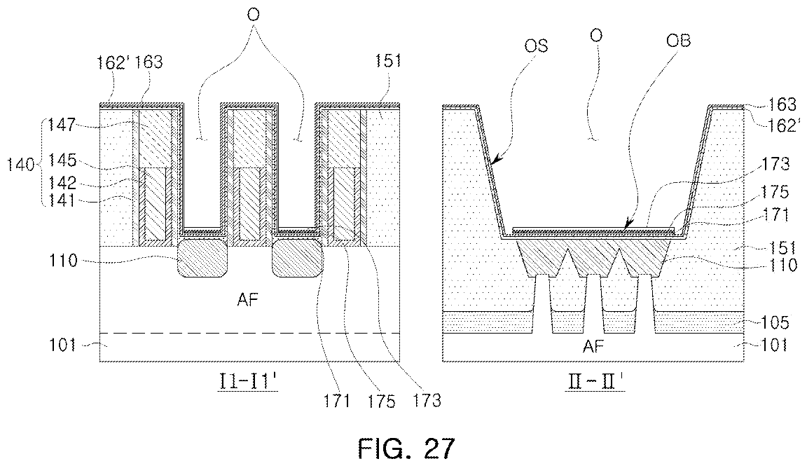

Referring to FIG. 27, by using the remaining mask layer 173, the portion of the barrier capping layer 170 on the sidewall OS of the opening O may be removed and only the portion of the first layer 171 and second layer 175 of the barrier capping layer 170 on the bottom surface OB of the opening O, e.g., only the portion corresponding to the source/drain region 110, may remain. This process may be performed using wet etching.

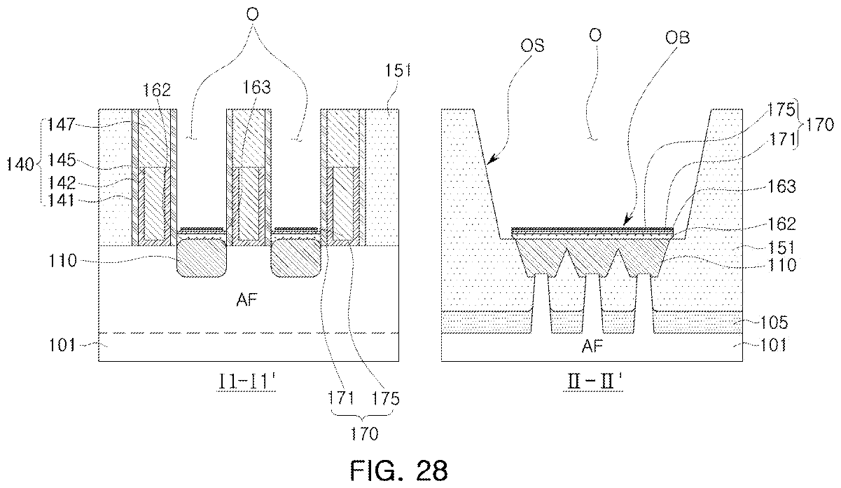

Referring to FIG. 28, the mask layer 173 may be removed from the barrier capping layer 170, and portions of at least one of the first barrier layer 163 and the metal layer 162′ on the sidewall OS of the opening O may be selectively removed. After the selective removal process, an annealing process for siliciding the metal layer 162′ may be performed to a desired metal silicide layer 162.

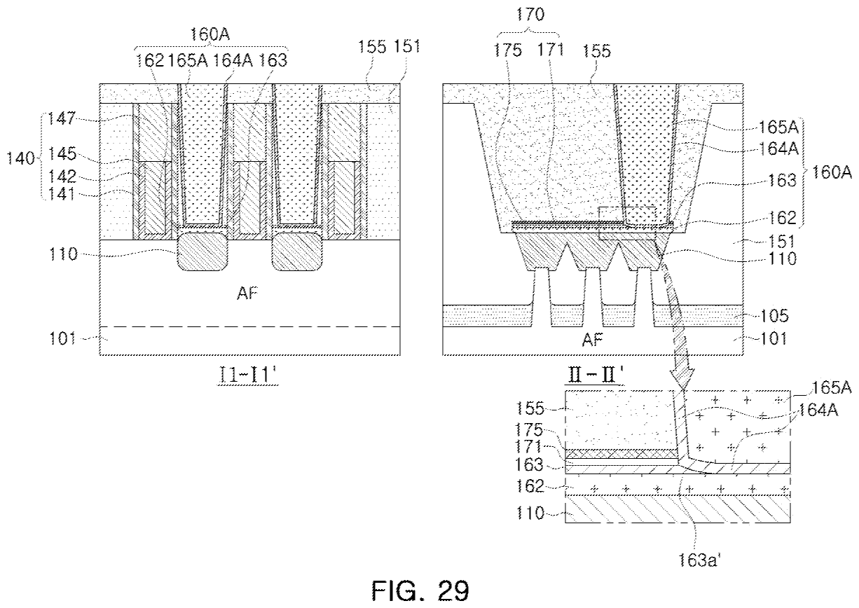

Referring to FIG. 29, a filling insulating portion 155 may fill the opening O, a contact hole CH may be formed in the filling insulating portion 155 to expose one region of the metal silicide layer 162, and a second barrier layer 164A and a first contact plug 165A may be sequentially formed in the contact hole CH. A series of processes may be performed similarly to the process described with reference to FIGS. 14 to 16. In an implementation, a portion of the first barrier layer 163 may remain on a bottom surface of the contact hole CH during formation of the contact hole CH. Even when the portion of the first barrier layer 163 remains, the remaining first barrier layer 163 may constitute a conductive barrier together with the second barrier layer 164A because the first barrier layer 163 is formed of a conductive material.

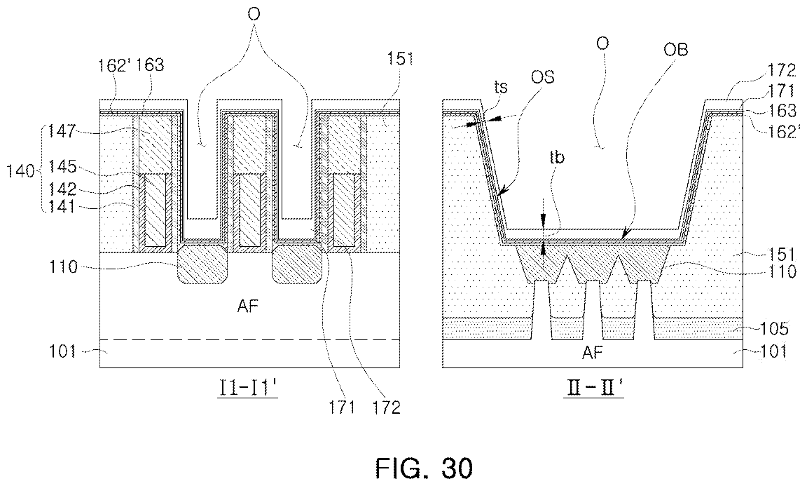

FIGS. 30 to 35 illustrate cross-sectional views of stages in a method of manufacturing a semiconductor device according to an example embodiment. The method of manufacturing a semiconductor device according to the present embodiment will be appreciated as a method of manufacturing the semiconductor device 100C illustrated in FIG. 6.

Referring to FIG. 30, after the resultant structure illustrating in FIG. 8, e.g., the metal layer 162′ and the first barrier layer 163 may be sequentially formed, a barrier capping layer 170′ may be formed on the interlayer dielectric 151 and the source/drain region 110. The barrier capping layer 170 of the present embodiment may have a double-layer structure including different two layers formed of the same material. For example, the barrier capping layer 170′ may both be formed of silicon oxide. In an implementation, a first layer 171 may be densely formed using ALD, and a second layer 172 formed on the first layer 171 may be formed CVD. In the present embodiment, a portion of the second layer 172 on a sidewall of an opening may have a thickness smaller than a thickness of other portions thereof. The second layer 172 may be formed using HDP CVD.

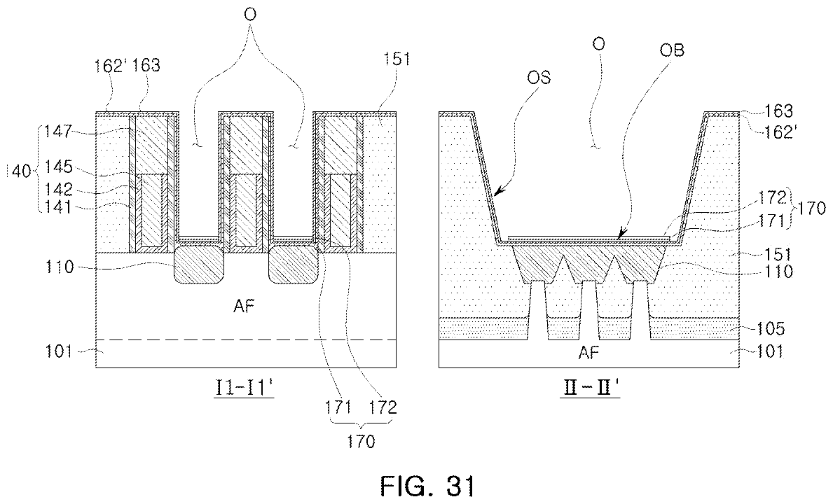

Referring to FIG. 31, wet etching may be performed until a portion of the second layer 172 on the sidewall OS of the opening O is removed. Even after the portion of the second layer 172 on the sidewall OS of the opening O is removed, the second layer 172 on the bottom surface OB of the opening O (previously formed to have the relatively great thickness tb) may remain. The remaining second layer 172 may be used as a mask in a subsequent process.

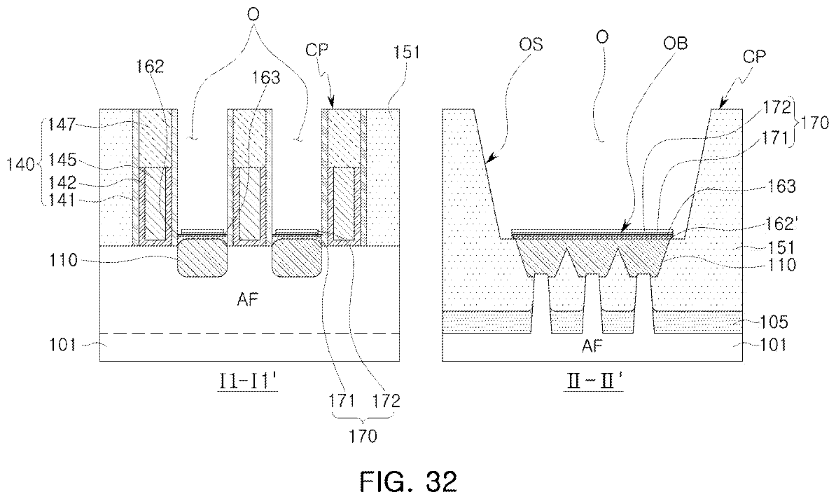

Referring to FIG. 32, a metal layer 162′ and a first barrier layer 163 may be selectively removed together with the first layer 171 using the remaining second layer 172 as a mask. This process may be performed using wet etching.

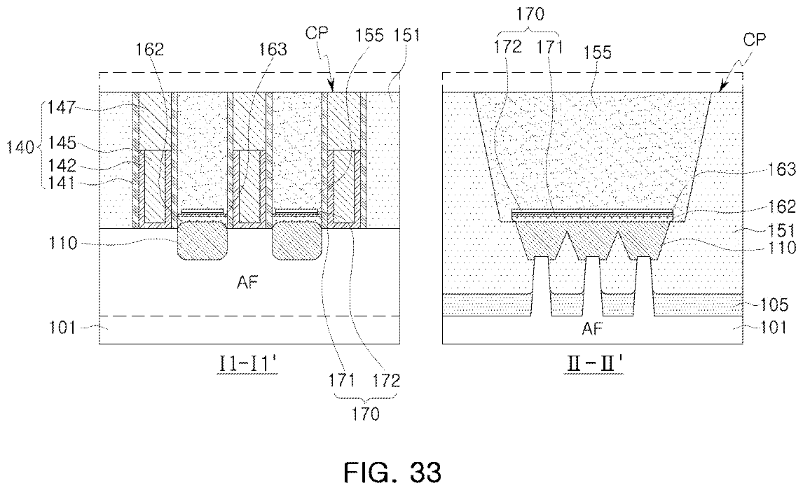

Referring to FIG. 33, the metal layer 162′ may be annealed to form a metal silicide layer and to form a filling annealing portion 155 to fill the opening O. A CMP process may be performed to remove the filing insulating portion 155 on a top surface of the interlayer dielectric 151 (removed by a thickness of a dotted portion). Thus, the interlayer dielectric 151 and filling insulating portion 155 may have a substantially planar surface with the gate structure 140.

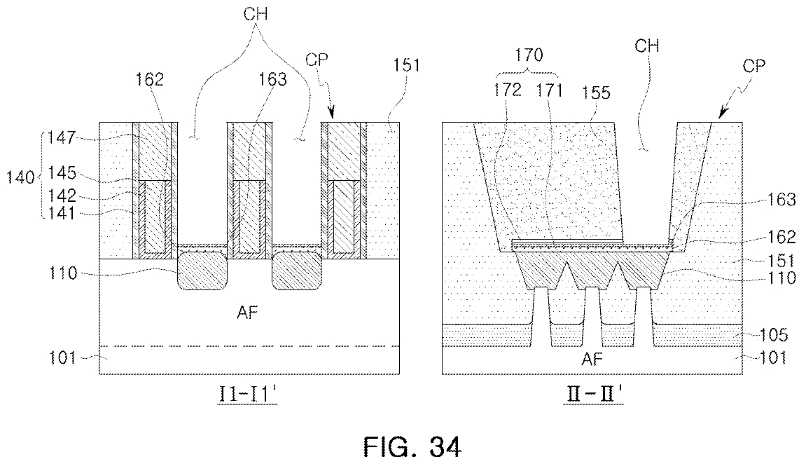

Referring to FIG. 34, a contact hole CH may be formed in the filling insulating portion 155 to expose one region of the first barrier layer 163. During formation of the contact hole CH, only the barrier capping layer 170′ may be removed from a bottom surface of the contact hole CH and the first barrier layer 163 may remain while slightly decreasing in thickness. Referring to FIG. 35, a second barrier layer 164A and a first contact plug 165A may be sequentially formed in the contact hole CH.

As described above, according to example embodiments, a contact having a structure that decreases in size at an upper portion thereof while maintaining a contact area at a lower portion thereof may be introduced to a source/drain region to help reduce a defect caused by integration or parasitic capacitance depending on a contact area without degradation of device performance. Even after silicidation of a metal layer, a first barrier layer on the metal layer may remain. Thus, silicide loss caused by removal of the first barrier layer may be prevented and a dispersion problem may be addressed accordingly.

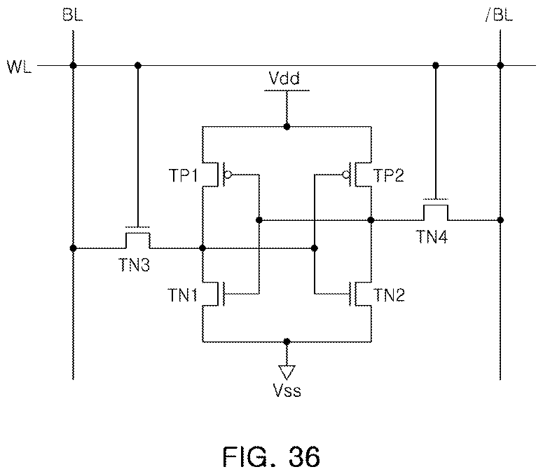

FIG. 36 illustrates a circuit diagram of an SRAM cell including a semiconductor device according to an example embodiment.

Referring to FIG. 36, a single cell in an SRAM may include first and second driving transistors TN1 and TN2, first and second load transistors TP1 and TP2, and first and second access transistors TN3 and TN4. In this case, sources of the first and second driving transistors TN1 and TN2 may be connected to a ground voltage line Vss, and sources of the first and second load transistors TP1 and TP may be connected to a power supply voltage line Vdd.

The first driving transistor TN1 including an NMOS transistor and the first load transistor TP1 including a PMOS transistor may constitute a first inverter, and the second driving transistor TN2 including an NMOS transistor and the second load transistor TP2 including a PMOS transistor may constitute a second inverter. At least one of the first and second load transistors TP1 and TP2 may include a semiconductor devices according to various example embodiments described with reference to FIG. 1 to FIG. 6.

Output terminals of the first and second inverters may be connected to sources of the first and second access transistors TN3 and TN4. Input and output terminals of the first and second inverters may intersect each other and be connected to each other. Drains of the first and second access transistors TN3 and TN4 may be connected to first and second bitlines BL and /BL, respectively.

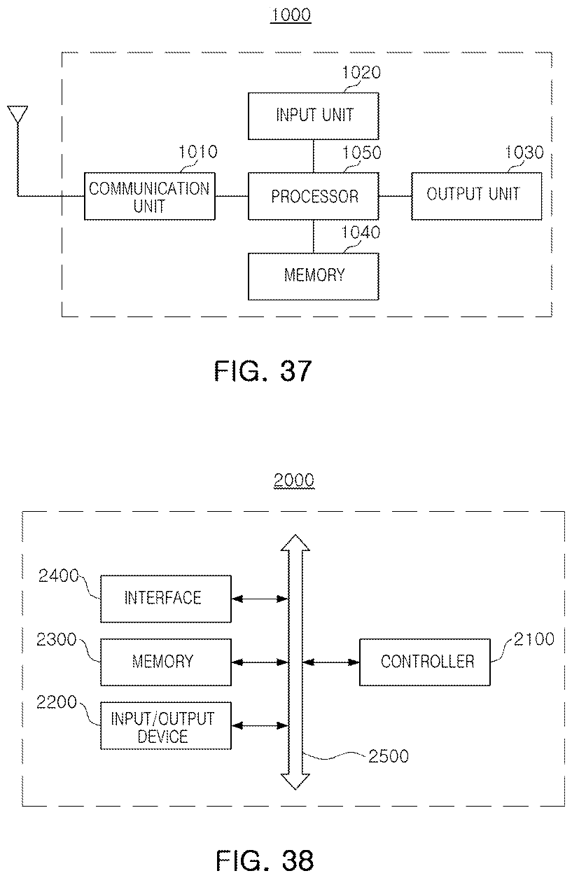

FIG. 37 illustrates a block diagram of an electronic apparatus including a semiconductor device according to an example embodiment.

Referring to FIG. 37, an electronic apparatus 1000 according to the example embodiment may include a communications unit 1010, an input unit 1020, an output unit 1030, a memory 1040, and a processor 1050.

The communications unit 1010 may include a wired or wireless communications module, a wireless Internet module, a local area communications module, a global positioning system (GPS) module, a mobile communications module, and the like. The wired or wireless communications module included in the communications unit 1010 may be connected to external communications networks according to various communications standard specifications to transmit and receive data.

The input unit 1020 may be a module provided to control an operation of the electronic apparatus 1000 by a user, and may include a mechanical switch, a touchscreen, a voice recognition module, and the like. Also, the input unit 1020 may include a mouse operating in a track ball or a laser pointer scheme or a finger mouse device. The input unit 1020 may further include various sensor modules allowing a user to input data thereto.

The output unit 1030 may output information processed in the electronic apparatus 1000 in a sound or image form, and the memory 1040 may store programs for the processing and the control of the processor 1050. The processor 1050 may transmit a command to the memory 1040 according to a required operation to store or retrieve data.

The memory 1040 may be embedded in the electronic apparatus 1000 to communicate with the processor 1050 directly or communicate with the processor 1050 through a separate interface. When the memory 1040 communicates with the processor 1050 through a separate interface, the processor 1050 may store or retrieve data through various interface standards such as SD, SDHC, SDXC, MICRO SD, USB, and the like.

The processor 1050 may control operations of respective components included in the electronic apparatus 1000. The processor 1050 may perform control and processing in association with voice communications, video telephony, data communications, and the like, or may perform control and processing for multimedia reproduction and management. The processor 1050 may process an input transferred from a user through the input unit 1020, and may output results thereof through the output unit 1030. Additionally, the processor 1050 may store data used to control the operation of the electronic apparatus 1000 as described above in the memory 1040, or fetch data from the memory 1040. At least one of the processor 1050 and the memory 1040 may include the semiconductor devices according to various example embodiments described with reference to FIGS. 1 to 6.

FIG. 38 illustrates a schematic diagram of a system including a semiconductor device according to an example embodiment.

Referring to FIG. 38, a system 2000 may include a controller 2100, an input/output device 2200, a memory 2300, and an interface 2400. The system 2000 may transmit or receive mobile system or information. Examples of the mobile system may include PDAs, portable computers, web tablets, wireless phones, mobile phones, digital music players, and memory cards.

The controller 2100 may execute a program and control the system 3000. The controller 2100 may be a microprocessor, a digital signal processor, a microcontroller, or a device similar thereto.

The input/output device 2200 may be used to input or output data to or from the system 2000. The system 2000 may be connected to an external device, such as a personal computer or networks, and may exchange data with the external device. The input/output device 2200 may be a keypad, a keyboard, or a display device.

The memory 2300 may store a code and/or data for operating the controller 3100 and/or store data having been processed by the controller 2100.

The interface 2400 may be a data transmission path between the system 3000 and an external device. The controller 2100, the input/output device 2200, the memory 3300, and the interface 2400 may be in communication with one another via a bus 2500.

At least one of the controller 2100 or the memory 2300 may include the semiconductor devices according to various example embodiments described with reference to FIG. 1 and FIG. 19.

By way of summation and review, in order to manufacture semiconductor devices having a fine pattern in response to the tendency for high degrees of integration in semiconductor devices, patterns having narrow widths or short separation distances may be used. In order to overcome any limitations of operating characteristics resulting from size reduction of planar metal oxide semiconductor FETs (MOSFETs), semiconductor devices including fin field effect transistors (FinFETs) with a three-dimensional structure may be used.

As set forth above, according to example embodiments, a contact having a structure that decreases in size at an upper portion thereof while maintaining a contact area at a lower portion thereof may be introduced to a source/drain region to help reduce a defect caused by integration or parasitic capacitance depending on a contact area without degradation of device performance. A height of the contact may remain constant using uniform deposition. Even after silicidation of a metal layer, a first barrier layer (also called protective barrier layer) on the metal layer may remain. Thus, silicide loss caused by removal of the first barrier layer may be prevented and a dispersion issue may be addressed accordingly.

One or more embodiments may provide a semiconductor device having an improved integration density while maintaining device performance.

An One or more embodiments may provide a method of manufacturing a semiconductor device having improved integration density while maintaining device performance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a substrate including an active fin extending in a first direction;
a gate structure extending in a second direction to intersect the active fin;
a source/drain region on the active fin;
a metal silicide layer on the source/drain region;
a filling insulating portion on the metal silicide layer, the filling insulating portion having a contact hole connected to a portion of the metal silicide layer;
a protective barrier layer between the metal silicide layer and the filing insulating portion; and
a contact plug in the contact hole and electrically connected to the portion of the metal silicide layer.

2. The semiconductor device as claimed in claim 1, further comprising a barrier capping layer between the protective barrier layer and the filling insulating portion, the barrier capping layer including a material different from a material of the protective barrier layer.

3. The semiconductor device as claimed in claim 2, wherein the barrier capping layer includes a silicon oxide or a silicon nitride.

4. The semiconductor device as claimed in claim 2, wherein the barrier capping layer includes two or more layers formed of materials that are different from each other.

5. The semiconductor device as claimed in claim 4, wherein the barrier capping layer includes:
a first layer including a silicon oxide, and
a second layer on the first layer and including a silicon nitride.

6. The semiconductor device as claimed in claim 1, wherein the protective barrier layer extends to the portion of the metal silicide layer underlying the contact hole.

7. The semiconductor device as claimed in claim 6, wherein an extending portion of the protective barrier layer has a thickness that is less than a thickness of the other portion of the protective barrier layer.

8. The semiconductor device as claimed in claim 1, further comprising a conductive barrier layer between the metal silicide layer and the contact plug and between an inner sidewall of the contact hole and the contact plug.

9. The semiconductor device as claimed in claim 8, wherein the conductive barrier layer has a thickness that is different from a thickness of the protective barrier layer.

10. The semiconductor device as claimed in claim 8, wherein at least one of the protective barrier layer and the conductive barrier layer includes titanium nitride (TiN), tantalum nitride (TaN), aluminum nitride (AlN), or tungsten nitride (WN).

11. The semiconductor device as claimed in claim 10, wherein the protective barrier layer and the conductive barrier layer include the same material.

12. The semiconductor device as claimed in claim 1, wherein the filling insulating portion covers a top surface of the gate structure.

13. The semiconductor device as claimed in claim 1, wherein the metal silicide layer includes a silicide layer including titanium (Ti), cobalt (Co), nickel (Ni), tantalum (Ta), or platinum (Pt).

14. A semiconductor device, comprising:
a substrate including a plurality of active fins extending in a first direction;
a gate structure extending in a second direction, different from the first direction, to intersect the plurality of active fins;
source/drain regions on the plurality of active fins on at least one side of the gate structure;
an interlayer dielectric on the gate structure and the plurality of active fins, the interlayer dielectric having an opening exposing the source/drain regions;
a metal silicide layer on the source/drain regions;
a filling insulating portion in the opening of the interlayer dielectric, the filling insulating portion having a contact hole connected to a portion of the metal silicide layer;
a first barrier layer between the metal silicide layer and the filling insulating portion;
a barrier capping layer between the first barrier layer and the filling insulating portion, the barrier capping layer including a material that is different from a material of the first barrier layer;
a contact plug in the contact hole and electrically connected to the source/drain regions through the metal silicide layer; and
a second barrier layer between the metal silicide layer and the contact plug and between an inner sidewall of the contact hole and the contact plug.

15. The semiconductor device as claimed in claim 14, wherein:
the first barrier layer includes titanium nitride (TiN), tantalum nitride (TaN), aluminum nitride (AlN), or tungsten nitride (WN), and
the barrier capping layer includes a silicon oxide or a silicon nitride.

16. The semiconductor device as claimed in claim 15, wherein the barrier capping layer includes:
a first layer on the first barrier layer and including a silicon oxide, and
a second layer on the first layer and including a silicon nitride.

17. The semiconductor device as claimed in claim 15, wherein the barrier capping layer includes first and second layers, the first and second layers having different physical properties, while being formed of the same material.

18. A semiconductor device, comprising:
a substrate including a plurality of active fins;
source/drain regions on the plurality of active fins;
a metal silicide layer on the source/drain regions;
a filling insulating portion on the metal silicide layer, the filling insulating portion having a contact hole connected to a portion of the metal silicide layer;
a first barrier layer between the metal silicide layer and the filling insulating portion;
a barrier capping layer between the first barrier layer and the filling insulating portion, the barrier capping layer including a material that is different from a material of the first barrier layer;
a contact plug in the contact hole and electrically connected to the portion of the metal silicide layer; and
a second barrier layer between the metal silicide layer and the contact plug and between an inner sidewall of the contact hole and the contact plug.

19. The semiconductor device as claimed in claim 18, wherein:
the first barrier layer extends to the portion of the metal silicide layer underlying the contact hole, and
the second barrier layer is on an extended portion of the first barrier layer.

20. The semiconductor device as claimed in claim 18, wherein an area of a top surface of the contact plug is smaller than an area in which the metal silicide layer is disposed.

21.-25. (canceled)
